(19) United States
(12) Patent Application Publication
(10) Pub. No.: US 2023/0206987 A1
(43) Pub. Date: Jun. 29, 2023

(54) INTEGRATED CIRCUIT STRUCTURE, MEMORY, AND INTEGRATED CIRCUIT LAYOUT

(71) Applicant: CHANGXIN MEMORY TECHNOLOGIES, INC., Hefei City (CN)

(72) Inventors: Jing XU, Hefei City (CN); Yingdong GUO, Hefei City (CN); Enpeng GAO, Hefei City (CN)

(21) Appl. No.: 17/807,751

(22) Filed: Jun. 20, 2022

Related U.S. Application Data
(63) Continuation of application No. PCT/CN2022/078102, filed on Feb. 25, 2022.

(30) Foreign Application Priority Data
Dec. 29, 2021 (CN) 202111643060.1

(51) Int. Cl. G11C 11/4078; G11C 11/4076; G11C 11/4093

(52) U.S. Cl. CPC G11C 11/4078; G11C 11/4076; G11C 11/4093

(57) ABSTRACT

The integrated circuit layout includes: a data pad; an electro-static discharge circuit, located at one side of the data pad and electrically connected to the data pad; a first transmission circuit, located at a side of the electro-static discharge circuit which faces towards the data pad, wherein the first transmission circuit is electrically connected to the electro-static discharge circuit through a first bus; a second transmission circuit, located at a side of the electro-static discharge circuit which is away from the first transmission circuit, wherein the second transmission circuit is electrically connected to the electro-static discharge circuit through a second bus. One of the first transmission circuit and the second transmission circuit is configured to transmit data from the data pad to a memory array, and the other is configured to receive data from the memory array and transmit the data to the data pad.

### CROSS REFERENCE TO RELATED APPLICATIONS

This is a continuation of International Application No. PCT/CN2022/078102, filed on Feb. 25, 2022, which claims the priority to Chinese Patent Application No. 202111643060.1, titled “INTEGRATED CIRCUIT STRUCTURE, MEMORY, AND INTEGRATED CIRCUIT LAYOUT” and filed on Dec. 29, 2021. The entire contents of International Application No. PCT/CN2022/078102 and Chinese Patent Application No. 202111643060.1 are incorporated herein by reference.

### TECHNICAL FIELD

Embodiments of the present disclosure relate to, but not limited to, an integrated circuit structure, a memory, and an integrated circuit layout.

### BACKGROUND

As a commonly used semiconductor memory in computers, a dynamic random access memory (DRAM) is composed of many repeated memory cells. Each memory cell typically includes a capacitor and a transistor. In the transistor, the gate is connected to the word line, the drain is connected to the bit line, and the source is connected to the capacitor. The voltage signal on the word line controls the transistor to turn on or off, and then the data information stored in the capacitor is read through the bit line, or data information is written into the capacitor through the bit line for storage.

However, due to a limited memory area, lots of wires that are densely arranged are easily coupled to each other, thus affecting each other. Moreover, the whole memory occupies a large area, which increases the cost. Therefore, it is necessary to optimize the layout and wiring of circuit structures in the memory.

### SUMMARY

According to some embodiments of the present disclosure, an aspect of the embodiments of the present disclosure provides an integrated circuit structure, including: a data pad; an electro-static discharge circuit, located at one side of the data pad and electrically connected to the data pad; a first transmission circuit, located at a side of the electro-static discharge circuit which faces towards the data pad, wherein the first transmission circuit is electrically connected to the electro-static discharge circuit through a first bus; a second transmission circuit, located at a side of the electro-static discharge circuit which is away from the first transmission circuit, wherein the second transmission circuit is electrically connected to the electro-static discharge circuit through a second bus. One of the first transmission circuit and the second transmission circuit is configured to transmit data from the data pad to a memory array, and the other is configured to receive data from the memory array and transmit the data to the data pad.

According to some embodiments of the present disclosure, another aspect of the embodiments of the present disclosure further provides a memory, including: a memory cell; and the integrated circuit structure described above.

According to some embodiments of the present disclosure, another aspect of the embodiments of the present disclosure further provides an integrated circuit layout, including: a data pad region, configured to define positions of a plurality of data pads located in a same row; an electro-static discharge region, located at one side of the data pad region and configured to define positions of a plurality of electro-static discharge circuits; a first transmission region, located between the data pad region and the electro-static discharge region and configured to define positions of a plurality of first transmission circuits located in a same row, wherein the first transmission circuit is electrically connected to the electro-static discharge circuit through a first bus; a second transmission region, located at a side of the electro-static discharge region which is away from the first transmission region and configured to define positions of a plurality of second transmission circuits located in the same row, wherein the second transmission circuit is electrically connected to the data pad through a second bus. One of the first transmission circuit and the second transmission circuit is configured to transmit data from the data pad to a memory array, and the other is configured to receive data from the memory array and transmit the data to the data pad.

### BRIEF DESCRIPTION OF THE DRAWINGS

One or more embodiments are described illustratively by use of corresponding drawings. The illustrative description does not constitute any limitation on the embodiments. Unless otherwise expressly specified, the drawings do not constitute a scale limitation. To describe the technical solutions in the embodiments of the present disclosure or in the prior art more clearly, the following outlines the drawings to be used in the embodiments of the present disclosure. Evidently, the drawings outlined below are merely some embodiments of the present disclosure. A person of ordinary skill in the art may derive other drawings from the outlined drawings without making any creative effort.

FIG. 1 is a partial schematic structural diagram of an integrated circuit structure corresponding to a data pad;

FIG. 2 is a partial schematic structural diagram of an integrated circuit structure;

FIG. 3 to FIG. 8 are 6 partial schematic structural diagrams of an integrated circuit structure corresponding to a data pad according to an embodiment of the present disclosure;

FIG. 9 is a partial schematic structural diagram of an integrated circuit structure according to an embodiment of the present disclosure;

FIG. 10 is a schematic diagram of partial transmission path layout of an integrated circuit provided in FIG. 9;

FIG. 11 is a schematic diagram of partial transmission path layout of an integrated circuit provided in FIG. 2;

FIG. 12 is a schematic diagram of a structure between a third bus or a fourth bus and a seventh bus or an eighth bus in FIG. 10;

FIG. 13 is a schematic structural diagram of a layout corresponding to an integrated circuit provided in FIG. 3;

FIG. 14 is a schematic structural diagram of a layout corresponding to an integrated circuit provided in FIG. 9; and

FIG. 15 is a schematic structural diagram of a layout corresponding to an integrated circuit provided in FIG. 10.

### DETAILED DESCRIPTION

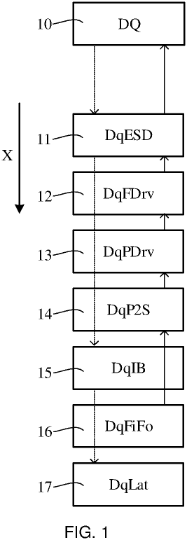

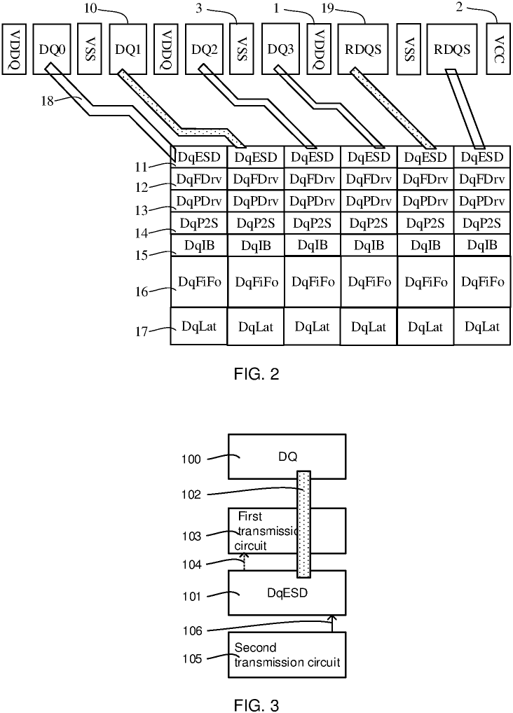

The arrangement and wiring of circuit structures in a memory need to be optimized. FIG. 1 is a partial schematic structural diagram of an integrated circuit structure corresponding to a data pad; FIG. 2 is a partial schematic structural diagram of an integrated circuit structure.

Referring to FIG. 1, the integrated circuit structure includes: a data pad 10, and an electro-static discharge circuit 11, a drive circuit 12, a pre-drive circuit 13, a serializer circuit 14, an input buffer circuit 15, a first-in first-out circuit 16, and a latch circuit 17 that are sequentially arranged along a direction X of moving away from the data pad 10. When data is written into a memory array, a transmission path of the written data is as follows: the data pad 10, the electro-static discharge circuit 11, the input buffer circuit 15, and the latch circuit 17 in sequence. When data is read from the memory array, a transmission path of the read data is as follows: the first-in first-out circuit 16, the serializer circuit 14, the pre-drive circuit 13, the drive circuit 12, the electro-static discharge circuit 11, and the data pad 10 in sequence.

It is clear that, in the process of writing data into the memory array, the transmission path of the written data needs to bypass the drive circuit 12, the pre-drive circuit 13, and the serializer circuit 14 that are located between the electro-static discharge circuit 11 and the input buffer circuit 15, and also needs to bypass the first-in first-out circuit 16 between the input buffer circuit 15 and the latch circuit 17, which will increase the length of the transmission path of the written data. In the process of reading data from the memory array, the transmission path of the read data needs to bypass the input buffer circuit 15 between the first-in first-out circuit 16 and the serializer circuit 14, which will also increase the length of the transmission path of the read data. Therefore, regardless of the data writing or reading phase, the length of the data transmission path includes an extra bypass wiring length, which is adverse to reducing the parasitic capacitance of the integrated circuit structure and also adverse to simplifying the overall layout of the integrated circuit structure.

In addition, referring to FIG. 2, the integrated circuit structure includes: a plurality of data pads 10 located in a same row, a plurality of electro-static discharge circuits 11 located in a same row, a plurality of drive circuits 12 located in a same row, a plurality of pre-drive circuits 13 located in a same row, a plurality of serializer circuits 14 located in a same row, a plurality of input buffer circuits 15 located in a same row, a plurality of first-in first-out circuits 16 located in a same row, and a plurality of latch circuits 17 located in a same row, where the data pad 10, the electro-static discharge circuit 11, the drive circuit 12, the pre-drive circuit 13, the serializer circuit 14, the input buffer circuit 15, the first-in first-out circuit 16, and the latch circuit 17 correspond to each other; and re-wiring layers 18, each located between the data pad 10 and the electro-static discharge circuit 11, and configured to electrically connect the data pad 10 and the electro-static discharge circuit 11, wherein the re-wiring layers 18 correspond to the data pads 10 in a one-to-one manner.

Because the re-wiring layer 18 requires a certain width of the gap between the data pad 10 and the electro-static discharge circuit 11, it is apparent that the gap region between the data pad 10 and the electro-static discharge circuit 11, i.e., the region where the re-wiring layer 18 is located, has low spatial utilization, which is adverse to improving the overall integration density of the integrated circuit structure.

In addition, the integrated circuit structure further includes a data sampling pad 19, a first power supply pad 1, a second power supply pad 2, and a ground pad 3. The data sampling pad 19 receives a data sampling signal, such as an RDQS signal; a level value of a first power supply received by the first power supply pad 1 may be higher than that of a second power supply received by the second power supply pad 2.

It should be noted that, DQ0, DQ1, DQ1, and DQ3 are used to indicate the data pads 10 in FIG. 2; DqESD is used to indicate the electro-static discharge circuit 11, DqFDrv is used to indicate the drive circuit 12, DqPDrv is used to indicate the pre-drive circuit 13, DqP2S is used to indicate the serializer circuit 14, DqIB is used to indicate the input buffer circuit 15, DqFiFo is used to indicate the first-in first-out circuit 16, and DqLat is used to indicate the latch circuit 17 in FIG. 1 and FIG. 2. In addition, in FIG. 1, the reference sign DQ is not followed by a number, and does not specifically refer to a particular data pad 10. In addition, RDQS is used to indicate the data sampling pad 19, VDDQ is used to indicate the first power supply pad 1, VCC is used to indicate the second power supply pad 2, and VSS is used to indicate the ground pad 3 in FIG. 2.

The embodiments of the present disclosure provide an integrated circuit structure, a memory, and an integrated circuit layout. In the integrated circuit structure, the first transmission circuit and the second transmission circuit are located at two sides of the electro-static discharge circuit respectively, so that both the first transmission circuit and the second transmission circuit have small distances from the electro-static discharge circuit, thereby reducing the lengths of the first bus and the second bus, thereby reducing the overall parasitic capacitance of the integrated circuit structure, to reduce the power consumption of the integrated circuit structure. In addition, due to the requirement of data transmission, the data pad and the electro-static discharge circuit are spaced apart by a certain distance, and the first transmission circuit is disposed between the data pad and the electro-static discharge circuit, thereby increasing the integration density of the integrated circuit structure and the overall layout area of the integrated circuit structure.

In order to make the objectives, technical solutions and advantages of the embodiments of the present disclosure clearer, the embodiments of the present disclosure are described below with reference to the accompanying drawings. However, a person skilled in the art may understand that in each embodiment of this application, many technical details are proposed to help readers better understand the embodiments of the present disclosure. However, the technical solutions claimed in the embodiments of the present disclosure can still be implemented based on variations and modifications of the following embodiments even without the technical details.

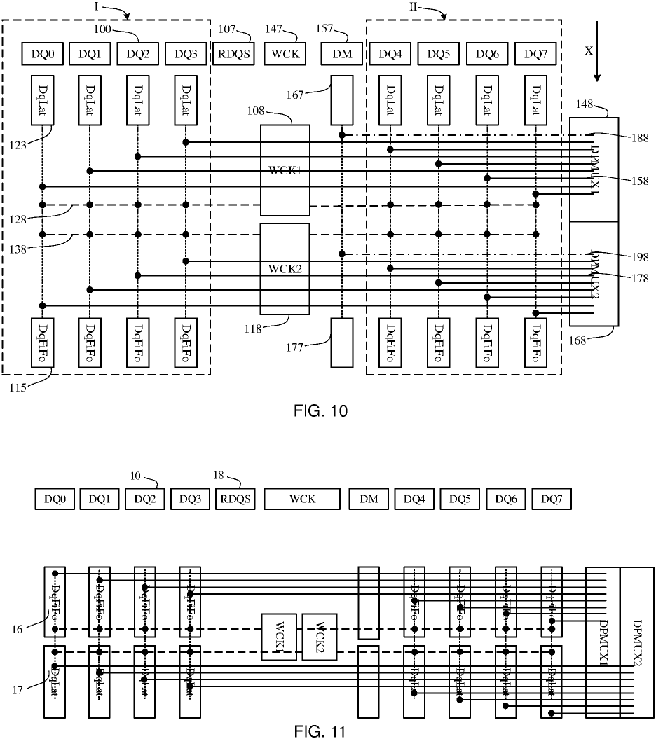

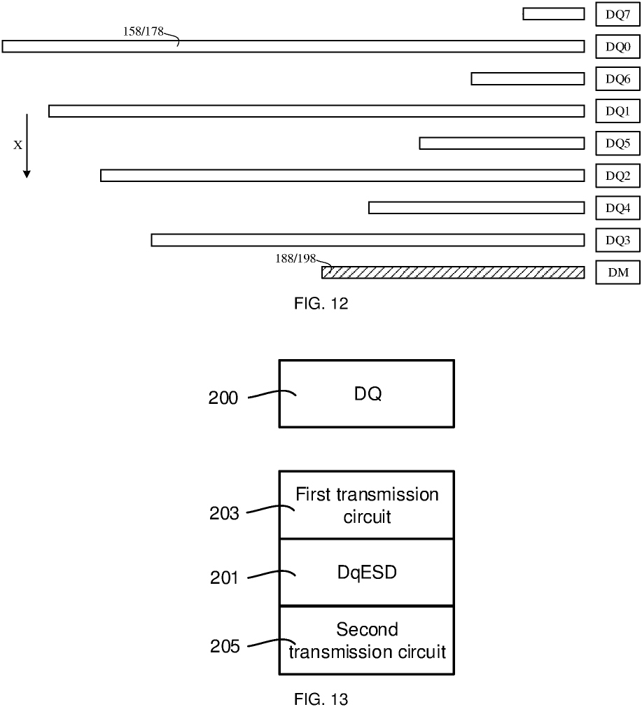

An embodiment of the present disclosure provides an integrated circuit structure. The integrated circuit structure provided by the first embodiment of the present disclosure is described in detail below with reference to the drawings. FIG. 3 to FIG. 8 are 6 partial schematic structural diagrams of an integrated circuit structure corresponding to a data pad according to an embodiment of the present disclosure; FIG. 9 is a partial schematic structural diagram of an integrated circuit structure according to an embodiment of the present disclosure; FIG. 10 is a schematic diagram of partial transmission path layout of an integrated circuit provided in FIG. 9; FIG. 11 is a schematic diagram of partial transmission path layout of an integrated circuit provided in FIG. 2; FIG. 12 is a schematic diagram of a structure between a third bus or a fourth bus 178 and a seventh bus or an eighth bus in FIG. 10.

It should be noted that, in FIG. 3 to FIG. 12, DqESD is used to indicate the electro-static discharge circuit 101, DqFDrv is used to indicate the drive circuit 125, DqPDrv is used to indicate the pre-drive circuit 145, DqP2S is used to indicate the serializer circuit 135, DqIB is used to indicate the input buffer circuit 113, DqFiFo is used to indicate the first-in first-out circuit 115, and DqLat is used to indicate the latch circuit 123.

Referring to FIG. 3, the integrated circuit structure includes: a data pad 100; an electro-static discharge circuit 101, located at a side of the data pad 100 and electrically connected to the data pad 100; a first transmission circuit 103, located at a side of the electro-static discharge circuit 101 which faces towards the data pad 100, where the first transmission circuit 103 is electrically connected to the electro-static discharge circuit 101 through a first bus 104; a second transmission circuit 105, located at a side of the electro-static discharge circuit 101 which is away from the first transmission circuit 103, where the second transmission circuit 105 is electrically connected to the electro-static discharge circuit 101 through a second bus 106. One of the first transmission circuit 103 and the second transmission circuit 105 is configured to transmit data from the data pad 100 to a memory array (not shown in the figure), and the other is configured to receive data from the memory array and transmit the data to the data pad 100. The data pad 100 may be electrically connected to the electro-static discharge circuit 101 through a re-wiring layer 102.

In this way, the circuit structure configured to store data into the memory array and the circuit structure configured to read data from the memory array are separate from each other, so that the first transmission circuit 103 and the second transmission circuit 105 are located at two sides of the electro-static discharge circuit 101 respectively. On one hand, the distances from the first transmission circuit 103 and the second transmission circuit 105 to the electro-static discharge circuit 101 are reduced, which helps reduce the lengths of the first bus 104 and the second bus 106, thereby helping reduce the overall parasitic capacitance of the integrated circuit structure, so as to reduce the power consumption of the integrated circuit structure. On the other hand, regardless of the data writing or reading phase, the first bus 104 does not need to bypass the second transmission circuit 105, and the second bus 106 does not need to bypass the first transmission circuit 103, which avoids unnecessary wiring lengths of the first bus 104 and the second bus 106, thereby further helping reduce the overall parasitic capacitance of the integrated circuit structure and simplify the overall layout of the integrated circuit structure.

In some embodiments, further referring to FIG. 3, the first transmission circuit 103 may be located between the electro-static discharge circuit 101 and the data pad 100. When the re-wiring layer 102 electrically connects the data pad 100 and the electro-static discharge circuit 101, the re-wiring layer 102 requires a certain width of the gap between the data pad 100 and the electro-static discharge circuit 101. Therefore, arranging the first transmission circuit 103 between the data pad 100 and the electro-static discharge circuit 101 helps improve the spatial utilization of the region where the re-wiring layer 102 is located, so as to improve the overall integration density of the integrated circuit structure and reduce the overall layout area of the integrated circuit structure.

In some embodiments, further referring to FIG. 3, the first transmission circuit 103 is configured to transmit data from the data pad 100 to the memory array, which corresponds to the data writing phase; the second transmission circuit 105 is configured to receive data from the memory array and transmit the data to the data pad 100, which corresponds to the data reading phase. In other embodiments, the first transmission circuit may also be configured to receive data from the memory array and transmit the data to the data pad; the second transmission circuit may also be configured to transmit data from the data pad to the memory array.

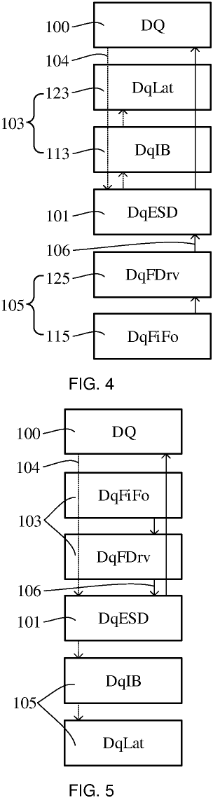

In some embodiments, referring to FIG. 4, the first transmission circuit 103 may include: an input buffer circuit 113, configured to receive data transmitted by the data pad 100 corresponding to the input buffer circuit 113; and a latch circuit 123, configured to receive and latch data outputted by the input buffer circuit 113, and output latched data in response to a write clock signal. It may be understood that, in this case, the first transmission circuit 103 is configured to transmit data from the data pad 100 to the memory array. In other embodiments, referring to FIG. 5, alternatively, the second transmission circuit 105 may include an input buffer circuit DqIB and a latch circuit DqLat, to transmit data from the data pad 100 to the memory array. In addition to receiving and latching data outputted by the input buffer circuit 113, the latch circuit 123 may further deserialize the data. That is, the latch circuit 123 has the function of a deserializer circuit, and then outputs latched data in response to a write clock signal.

It should be noted that, the distance between the input buffer circuit 113 and the electro-static discharge circuit 101 is different from the distance between the latch circuit 123 and the electro-static discharge circuit 101. For the electro-static discharge circuit 101, a positional relationship between the input buffer circuit 113 and the latch circuit 123 includes two situations as follows:

In the phase of transmitting data from the data pad 100 to the memory array, a transmission path of the written data is as follows: the data pad 100, the electro-static discharge circuit 101, the input buffer circuit 113, and the latch circuit 123 in sequence. In some embodiments, referring to FIG. 4, the input buffer circuit 113 is located between the latch circuit 123 and the electro-static discharge circuit 101. In this case, the first bus 104 sequentially passes through the electro-static discharge circuit 101, the input buffer circuit 113, and the latch circuit 123 without bypassing any circuit, which helps reduce the length of the first bus 104, so as to reduce the overall parasitic capacitance of the integrated circuit structure and simplify the overall layout of the integrated circuit structure.

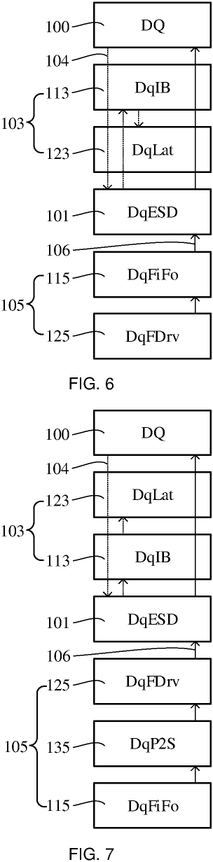

In other embodiments, referring to FIG. 6, the latch circuit 123 may also be located between the input buffer circuit 113 and the electro-static discharge circuit 101.

In some embodiments, further referring to FIG. 4, the second transmission circuit 105 may include: a first-in first-out circuit 115, configured to receive and transmit data from the memory array; a drive circuit 125, configured to receive data outputted by the first-in first-out circuit 115, and output data to the data pad 100, where the drive circuit 125 is located between the electro-static discharge circuit 101 and the first-in first-out circuit 115. It may be understood that, in this case, the second transmission circuit 105 is configured to receive data from the memory array and transmit the data to the data pad 100. In other embodiments, further referring to FIG. 5, alternatively, the first transmission circuit 103 may include an input buffer circuit and a latch circuit, to transmit data from the data pad to the memory array.

It should be noted that, the distance between the first-in first-out circuit 115 and the electro-static discharge circuit 101 is different from the distance between the drive circuit 125 and the electro-static discharge circuit 101. For the electro-static discharge circuit 101, a positional relationship between the first-in first-out circuit 115 and the drive circuit 125 includes two situations as follows:

In the process of receiving data from the memory array and transmitting the data to the data pad 100, a transmission path of the read data is as follows: the first-in first-out circuit 115, the drive circuit 125, the electro-static discharge circuit 101, and the data pad 100 in sequence. In some embodiments, referring to FIG. 4, the drive circuit 125 is located between the first-in first-out circuit 115 and the electro-static discharge circuit 101. In this case, the second bus 106 sequentially passes through the first-in first-out circuit 115, the drive circuit 125, and the electro-static discharge circuit 101 without bypassing any circuit, which helps reduce the length of the second bus 106, so as to reduce the overall parasitic capacitance of the integrated circuit structure and simplify the overall layout of the integrated circuit structure.

In other embodiments, referring to FIG. 6, the first-in first-out circuit 115 may alternatively be located between the drive circuit 125 and the electro-static discharge circuit 101.

In some embodiments, referring to FIG. 7, the second transmission circuit 105 may further include: a serializer circuit 135, located between the drive circuit 125 and the first-in first-out circuit 115, and configured to serialize data outputted by the first-in first-out circuit 115 and transmit serialized data to the drive circuit 125.

It may be understood that, the drive circuit 125 and the corresponding serializer circuit 135 form an output buffer circuit.

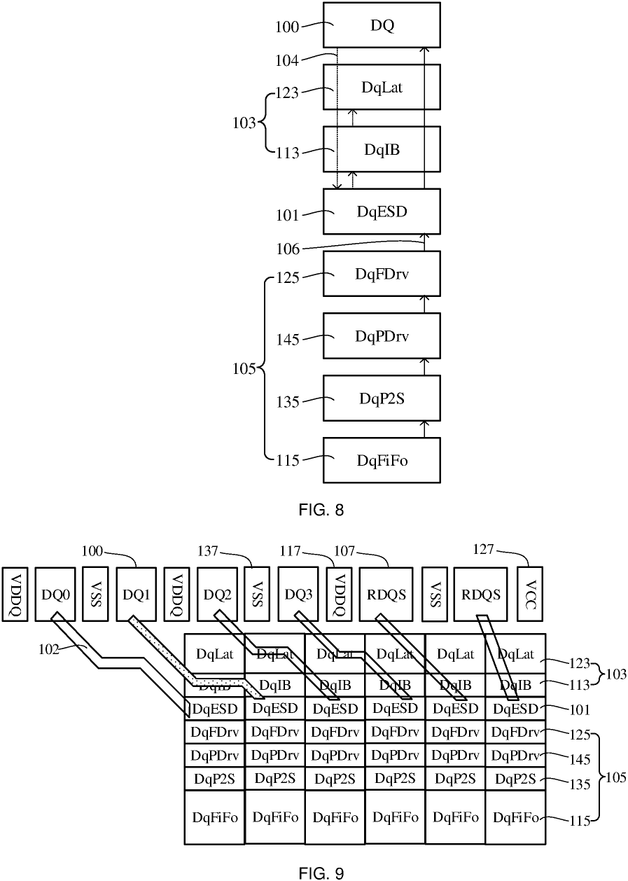

In some embodiments, referring to FIG. 8, the second transmission circuit 105 may further include: a pre-drive circuit 145, located between the drive circuit 125 and the first-in first-out circuit 115. In this way, the driving capability for data transmission can be improved through driving capabilities of the pre-drive circuit 145 and the drive circuit 125, so as to improve the accuracy of data transmission.

It should be noted that, in some embodiments, the second transmission circuit 105 may only include one of the serializer circuit 135 and the pre-drive circuit 145. In other embodiments, the second transmission circuit 105 may include both the serializer circuit 135 and the pre-drive circuit 145, and the pre-drive circuit 145 is located between the drive circuit 125 and the serializer circuit 135. In the phase of receiving data from the memory array and transmitting the data to the data pad 100, the transmission path of the read data may be as follows: the first-in first-out circuit 115, the serializer circuit 135, the pre-drive circuit 145, the drive circuit 125, the electro-static discharge circuit 101, and the data pad 100 in sequence. If the serializer circuit 135 is located between the drive circuit 125 and the first-in first-out circuit 115, and the pre-drive circuit 145 is located between the drive circuit 125 and the serializer circuit 135, the second bus 106 sequentially passes through the first-in first-out circuit 115, the serializer circuit 135, the pre-drive circuit 145, the drive circuit 125, and the electro-static discharge circuit 101 without bypassing any circuit, which helps reduce the length of the second bus 106, so as to reduce the overall parasitic capacitance of the integrated circuit structure and simplify the overall layout of the integrated circuit structure.

It should be noted that, regardless of whether the second transmission circuit 105 includes two sub-circuits (such as the first-in first-out circuit 115 and the drive circuit 125), or three sub-circuits (such as the first-in first-out circuit 115, the drive circuit 125 and the serializer circuit 135, or the first-in first-out circuit 115, the drive circuit 125 and the pre-drive circuit 145), or four sub-circuits (such as the first-in first-out circuit 115, the drive circuit 125, the serializer circuit 135, and the pre-drive circuit 145), the layout manner of the sub-circuits of the second transmission circuit 105 along direction X is not limited. FIG. 4 to FIG. 8 merely show examples for ease of description.

In some embodiments, referring to FIG. 9, the integrated circuit structure may include: a plurality of data pads 100 located in a same row, a plurality of electro-static discharge circuits 101 located in a same row, a plurality of first transmission circuits 103 located in a same row, and a plurality of second transmission circuits 105 located in a same row, where the data pad 100, the electro-static discharge circuit 101, the first transmission circuit 103, and the second transmission circuit 105 correspond to each other. A data pad 100 and the corresponding electro-static discharge circuit 101 are electrically connected through a re-wiring layer 102. Since the re-wiring layer 102 requires a certain width, a gap exists between the data pad 100 and the electro-static discharge circuit 101.

Therefore, referring to FIG. 2 and FIG. 9, arranging the first transmission circuit 103 between the data pad 100 and the electro-static discharge circuit 101 not only helps avoid unnecessary bypassing lengths in the first bus 104 and the second bus 106, so as to reduce the overall parasitic capacitance of the integrated circuit structure and simplify the overall layout of the integrated circuit structure, but also helps improve the spatial utilization of the region where the re-wiring layer 102 is located, so as to improve the overall integration density of the integrated circuit structure and reduce the overall layout area of the integrated circuit structure.

In some embodiments, further referring to FIG. 9, the integrated circuit structure may further include: a data sampling pad 107, a first power supply pad 117, a second power supply pad 127, and a ground pad 137. The data sampling pad 107 receives a data sampling signal, such as an RDQS signal; a level value of a first power supply received by the first power supply pad 117 may be higher than that of a second power supply received by the second power supply pad 127.

It should be noted that, DQ0, DQ1, DQ2, and DQ3 are used to indicate the data pads 100 in FIG. 9; in FIG. 3 to FIG. 8, the reference sign DQ is not followed by a number, and does not specifically refer to a particular data pad 100. In FIG. 9, RDQS is used to indicate the data sampling pad 107, VDDQ is used to indicate the first power supply pad 117, VCC is used to indicate the second power supply pad 127, and VSS is used to indicate the ground pad 137. FIG. 9 only schematically shows four data pads 100 located in the same row. In practical application, the number of data pads 100 in the integrated circuit structure is not limited.

In some embodiments, referring to FIG. 9 and FIG. 10, FIG. 10 is a schematic diagram of partial transmission path layout of an integrated circuit provided in FIG. 9. It should be noted that, in FIG. 10, DQ0, DQ1, DQ2...DQ7 are used to indicate the data pads 100, RDQS is used to indicate the data sampling pad 107, WCK is used to indicate a clock pad 147, DM is used to indicate a data mask pad 157, WCK1 is used to indicate a first clock processing circuit 108, WCK2 is used to indicate a second clock processing circuit 118, DPMUX1 is used to indicate a first data selection module 148, and DPMUX2 is used to indicate a second data selection module 168. FIG. 10 only schematically shows eight data pads 100 located in the same row. In practical application, the number of data pads 100 in the integrated circuit structure is not limited.

The integrated circuit structure may further include: a first clock processing circuit 108, configured to provide a first clock signal, where the first transmission circuit 103 outputs data from the data pad 100 in response to the first clock signal; and a second clock processing circuit 118, configured to provide a second clock signal, where the second transmission circuit 105 outputs data from the memory array in response to the second clock signal. Arrangement of positions of the first clock processing circuit 108 and the second clock processing circuit 118 corresponds to arrangement of positions of the first transmission circuit 103 and the second transmission circuit 105. That is, in the direction X, the first clock processing circuit 108 and the second clock processing circuit 118 are arranged up and down.

The first clock processing circuit 108 and the first transmission circuit 103 are connected through a fifth bus 128. In an example, the first clock processing circuit 108 is connected to the latch circuit 123 in the first transmission circuit 103 through the fifth bus 128. The second clock processing circuit 118 and the second transmission circuit 105 are connected through a sixth bus 138. In an example, the second clock processing circuit 118 is connected to the first-in first-out circuit 115 in the second transmission circuit 105 through the sixth bus 138.

FIG. 11 is a schematic diagram of partial transmission path layout of an integrated circuit provided in FIG. 2. FIG. 11 includes circuit structures such as the data pad, the latch circuit, the first-in first-out circuit, the first clock processing circuit, and the second clock processing circuit. It should be noted that, for ease of comparison and explanation, in FIG. 11, DQ0, DQ1...DQ7 also indicate the data pads, RDQS indicates the data sampling pad, WCK indicates the clock pad, DM indicates the data mask pad, DqLat indicates the latch circuit, DqFiFo indicates the first-in first-out circuit, WCK1 indicates the first clock processing circuit, and WCK2 indicates the second clock processing circuit.

Referring to FIG. 10 and FIG. 11, because the first clock processing circuit 108 and the second clock processing circuit 118 are arranged up and down along the direction X, the fifth bus 128 can be electrically connected to the first transmission circuit 103 without bypassing the second clock processing circuit 118, and the sixth bus 138 can be electrically connected to the second transmission circuit 105 without bypassing the first clock processing circuit 108, which helps avoid unnecessary bypassing lengths of the fifth bus 128 and the sixth bus 138, thereby helping further reduce the overall parasitic capacitance of the integrated circuit structure and the simplify the overall layout of the integrated circuit structure.

In some embodiments, further referring to FIG. 9 and FIG. 10, the integrated circuit structure may be divided into a first region I and a second region II. The first region I and the second region II each include a plurality of data pads 100 located in the same row, a plurality of electro-static discharge circuits 101 located in the same row, a plurality of first transmission circuits 103 located in the same row, and a plurality of second transmission circuits 105 located in the same row. The first clock processing circuit 108 and the second clock processing circuit 118 are located between the first region I and the second region II. The first region I and the second region II may include the same number of data pads 100, so that data paths from the first clock processing circuit 108 and the second clock processing circuit 118 to the first transmission circuit 103 and the second transmission circuit 105 corresponding to each data pad 100 are less different.

In some embodiments, referring to FIG. 9 and FIG. 10, the integrated circuit structure may further include: a first data selection module 148, connected to the plurality of first transmission circuits 103 through a plurality of third buses 158, where each third bus 158 corresponds to at least one of the first transmission circuits 103; and a second data selection module 168, connected to the plurality of second transmission circuits 105 through a plurality of fourth buses 178, where each fourth bus 178 corresponds to at least one of the second transmission circuits 105. The first data selection module 148 and the second data selection module 168 are connected to the memory array, and are located at a same side of the first transmission circuit 103 and the second transmission circuit 105, and arrangement of positions of the first data selection module 148 and the second data selection module 168 corresponds to arrangement of positions of the first transmission circuit 103 and the second transmission circuit 105. That is, along the direction X, the first data selection module 148 and the second data selection module 168 are arranged up and down.

FIG. 11 shows the first data selection module and the second data selection module. It should be noted that, for ease of comparison and explanation, in FIG. 11, DPMUX1 indicates the first data selection module, and DPMUX2 indicates the second data selection module.

Referring to FIG. 10 and FIG. 11, in the integrated circuit structure provided by the embodiments of the present disclosure, a large gap exists between the latch circuit 123 and the first-in first-out circuit 115, which, on one hand, helps increase gaps between the plurality of third buses 158, thereby reducing the parasitic capacitance between the plurality of third buses 158 to improve the accuracy of the written data, and on the other hand, helps increase gaps between the plurality of fourth buses 178, thereby helping reduce the parasitic capacitance between the plurality of fourth buses 178 to improve the accuracy of the read data. In addition, since the first data selection module 148 and the second data selection module 168 are arranged up and down along the direction X, the third bus 158 can be electrically connected to the first transmission circuit 103 without bypassing the second data selection module 168, or the fourth bus 178 can be electrically connected to the second transmission circuit 105 without bypassing the first data selection module 148, which avoids an unnecessary bypassing length in the third bus 158 or the fourth bus 178, thereby helping further reduce the overall parasitic capacitance of the integrated circuit structure and simplify the overall layout of the integrated circuit structure.

In some embodiments, the first data selection module 148 may be a data writing module, with one terminal electrically connected to the memory array and one terminal electrically connected to the data pad 100 through the first transmission circuit 103, to transmit a signal transmitted from the data pad 100 to the memory array. The second data selection module 168 may be a data reading module, with one terminal electrically connected to the memory array and one terminal electrically connected to the data pad 100 through the second transmission circuit 105, to process a signal transmitted from the memory array to the data pad 100. In an example, the first data selection module 148 is connected to the latch circuit 123 in the first transmission circuit 103 through the third bus 158, and the second data selection module 168 is connected to the first-in first-out circuit 115 in the second transmission circuit 105 through the fourth bus 178.

In some embodiments, referring to FIG. 9 and FIG. 10, the integrated circuit structure may further include: a data mask pad 157, located in a same row with the data pad 100 and configured to transmit a data mask signal; a third transmission circuit 167, located in a same row with the first transmission circuit 103 and configured to transmit the data mask signal from the data mask pad 157; and a fourth transmission circuit 177, located in a same row with the second transmission circuit 105 and configured to receive the data mask signal from the memory array and transmit the data mask signal to the data mask pad 157.

In some embodiments, the third transmission circuit 167 may be electrically connected to the first data selection module 148 through a seventh bus 188; the fourth transmission circuit 177 may be electrically connected to the second data selection module 168 through an eighth bus 198.

In some embodiments, referring to FIG. 9, FIG. 10, and FIG. 12, FIG. 12 is a schematic diagram of a structure between the third buses 158 or fourth buses 178 sequentially corresponding to the eight data pads 100 in FIG. 10 and the seventh bus 188 or eighth bus 198 corresponding to the data mask pad 157.

Along the direction X from the first transmission circuit 103 to the second transmission circuit 105, two initial third buses 158 have a largest length and a smallest length respectively; lengths of adjacent third buses 158 at odd-number positions among the plurality of third buses 158 change according to a first trend, and lengths of adjacent third buses 158 at even-number positions among the plurality of third buses 158 change according to a second trend. The first trend is one of ascending or descending, and the second trend is the other of ascending or descending. In this way, by configuring different lengths of two adjacent third buses 158, a direct opposite area between the two adjacent third buses 158 is reduced, which helps further reduce the parasitic capacitance between the adjacent third buses 158, so as to reduce the overall parasitic capacitance of the integrated circuit structure.

In addition, the length of the seventh bus 188 or the eighth bus 198 not only changes according to the first trend with the lengths of adjacent third buses 158 at odd-number positions, but also changes according to the second trend with the lengths of adjacent third buses 158 at even-number positions.

In some embodiments, referring to FIG. 9, FIG. 10 and FIG. 12, along the direction X from the first transmission circuit 103 to the second transmission circuit 105, two initial fourth buses 178 have a largest length and a smallest length respectively; lengths of adjacent fourth buses 178 at odd-number positions among the plurality of fourth buses 178 change according to a first trend, and lengths of adjacent fourth buses 178 at even-number positions among the plurality of fourth buses 178 change according to a second trend. The first trend is one of ascending or descending, and the second trend is the other of ascending or descending. In this way, by configuring different lengths of two adjacent fourth buses 178, a direct opposite area between the two adjacent fourth buses 178 is reduced, which helps further reduce the parasitic capacitance between the adjacent fourth buses 178, so as to reduce the overall parasitic capacitance of the integrated circuit structure.

It should be noted that, referring to FIG. 12, the two initial third buses 158 or fourth buses 178 are two third buses 158 or fourth buses 178 corresponding to the data pad DQ7 and the data pad DQ0; the third buses 158 or fourth buses 178 at odd-number positions are the third buses 158 or fourth buses 178 corresponding to the data pads DQ7, DQ6, DQ5, and DQ4; the third buses 158 or fourth buses 178 at even-number positions are the third buses 158 or fourth buses 178 corresponding to the data pads DQ0, DQ1, DQ2, and DQ3.

In addition, if the lengths of the adjacent third buses 158 or fourth buses 178 at odd-number positions change according to an ascending trend, along the direction X, the first initial third bus 158 or fourth bus 178 has the smallest length, and the second initial third bus 158 or fourth bus 178 has the largest length. If the lengths of the adjacent third buses 158 or fourth buses 178 at odd-number positions change according to a descending trend, along the direction X, the first initial third bus 158 or fourth bus 178 has the largest length, and the second initial third bus 158 or fourth bus 178 has the smallest length.

In summary, the first transmission circuit 103 and the second transmission circuit 105 are located at two sides of the electro-static discharge circuit 101 respectively, so that both the first transmission circuit 103 and the second transmission circuit 105 have small distances from the electro-static discharge circuit 101, thereby reducing the lengths of the first bus 104 and the second bus 106, thereby reducing the overall parasitic capacitance of the integrated circuit structure, to reduce the power consumption of the integrated circuit structure. In addition, due to the requirement of data transmission, the data pad 100 and the electro-static discharge circuit 101 are spaced apart by a certain distance, and the first transmission circuit 103 is disposed between the data pad 100 and the electro-static discharge circuit 101, thereby increasing the integration density of the integrated circuit structure and the overall layout area of the integrated circuit structure.

Another embodiment of the present disclosure provides a memory, including the integrated circuit structure provided by the foregoing embodiment. Parts that correspond to the foregoing embodiment are not described herein again.

The memory includes: a memory cell; and the integrated circuit structure provided by the foregoing embodiment. The memory may be a dynamic random access memory (DRAM), a static random access memory (SRAM), a magnetic random access memory (MRAM), a ferroelectric random access memory (FeRAM), a phase change random access memory (PCRAM), a NAND memory NAND, a NOR memory, or the like.

As can be learned from the analysis above, the first transmission circuit 103 and the second transmission circuit 105 in the integrated circuit structure are located at two sides of the electro-static discharge circuit 101 respectively, which helps reduce the overall parasitic capacitance of the integrated circuit structure, so as to reduce the power consumption of the integrated circuit structure, and also helps improve the integration density of the integrated circuit structure and reduce the overall layout area of the integrated circuit structure, thereby reducing the overall parasitic capacitance of the memory containing the integrated circuit structure to reduce the power consumption of the memory, improving the integration density of the memory, and reducing the overall layout area of the memory.

Another embodiment of the present disclosure provides an integrated circuit layout, for forming the integrated circuit structure provided by the foregoing embodiment. The integrated circuit layout provided by another embodiment of the present disclosure is descried in detail below with reference to FIG. 3 to FIG. 15. Parts that correspond to the foregoing embodiment are not described in detail herein again.

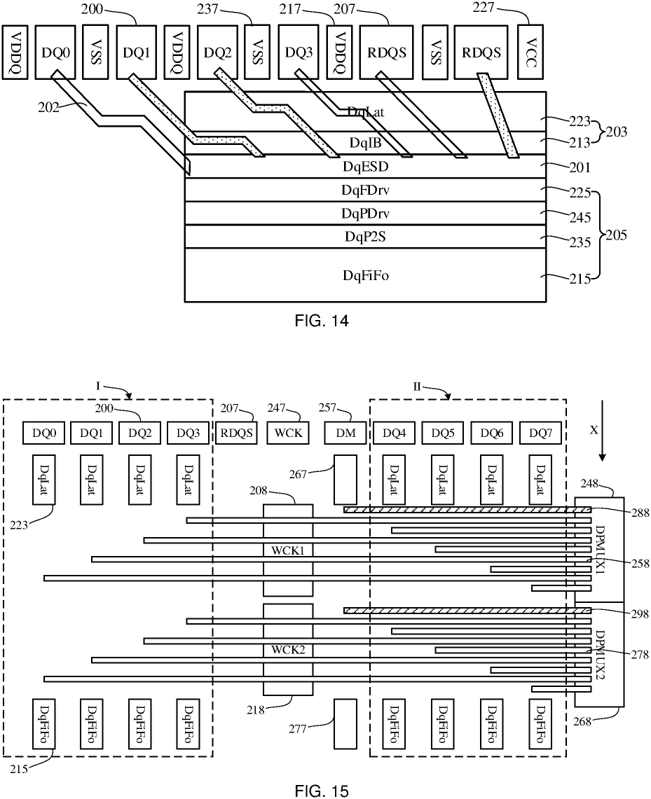

FIG. 13 is a schematic structural diagram of a layout corresponding to an integrated circuit provided in FIG. 3; FIG. 14 is a schematic structural diagram of a layout corresponding to an integrated circuit provided in FIG. 9; and FIG. 15 is a schematic structural diagram of a layout corresponding to an integrated circuit provided in FIG. 10.

Referring to FIG. 3 and FIG. 13, the integrated circuit layout includes: a data pad region 200, configured to define positions of a plurality of data pads 100 located in a same row; an electro-static discharge region 201, located at a side of the data pad region 200 and configured to define positions of a plurality of electro-static discharge circuits 101 located in a same row; a first transmission region 203, located between the data pad region 200 and the electro-static discharge region 201 and configured to define positions of first transmission circuits 103 located in a same row, where the first transmission circuit 103 is electrically connected to the electro-static discharge circuit 101 through a first bus 104; and a second transmission region 205, located at a side of the electro-static discharge region 201 which is away from the first transmission region 203 and configured to define positions of a plurality of second transmission circuits 105 located in a same row, where the second transmission circuit 105 is electrically connected to the data pad 100 through a second bus 106. One of the first transmission circuit 103 and the second transmission circuit 105 is configured to transmit data from the data pad 100 to a memory array (not shown in the figure), and the other is configured to receive data from the memory array and transmit the data to the data pad 100.

In this way, the distances from the first transmission region 203 and the second transmission region 205 to the electro-static discharge region 201 can be reduced, which helps reduce the lengths of the first bus 104 and the second bus 106, thereby reducing the overall parasitic capacitance of the integrated circuit structure formed according to the integrated circuit layout, so as to reduce the power consumption of the integrated circuit structure. On the other hand, arranging the first transmission region 203 between the data pad 100 and the electro-static discharge circuit 101 helps increase the utilization of the integrated circuit layout, to improve the overall integration density of the integrated circuit structure formed according to the integrated circuit layout and reduce the overall layout area of the integrated circuit structure.

In some embodiments, the first transmission circuit 103 is configured to transmit data from the data pad 100 to the memory array, and the second transmission circuit 105 is configured to receive data from the memory array and transmit the data to the data pad 100. In other embodiments, the first transmission circuit may also be configured to receive data from the memory array and transmit the data to the data pad; the second transmission circuit may also be configured to transmit data from the data pad to the memory array.

In some embodiments, referring to FIG. 9 and FIG. 14, the first transmission region 203 includes: an input buffer region 213, configured to define a plurality of input buffer circuits 113 located in a same row; and a latch region 223, located at a side of the input buffer region 213 which is away from the electro-static discharge region 201 and configured to define a plurality of latch circuits 123 located in a same row. It may be understood that, in this case, the first transmission region 203 is subsequently configured to transmit data from the data pad 100 to the memory array. In other embodiments, alternatively, the second transmission region may include the input buffer region and the latch region, so as to transmit data from the data pad to the memory array subsequently.

It should be noted that, in some embodiments, referring to FIG. 14, the input buffer region 213 is located between the latch region 223 and the electro-static discharge region 201; in other embodiments, alternatively, the latch region may be located between the input buffer region and the electro-static discharge region.

In some embodiments, further referring to FIG. 9 and FIG. 14, the second transmission region 205 includes: a first-in first-out region 215, configured to define a plurality of first-in first-out circuits 115 located in a same row; and a drive circuit region 225, located between the first-in first-out region 215 and the electro-static discharge region 201 and configured to define a plurality of drive circuits 125 located in a same row. It may be understood that, in this case, the second transmission region 205 is subsequently configured to receive data from the memory array and transmit the data to the data pad 100. In other embodiments, alternatively, the first transmission region may include the first-in first-out region and the drive circuit region, so as to transmit data from the data pad to the memory array subsequently.

It should be noted that, in some embodiments, referring to FIG. 14, the drive circuit region 225 is located between the first-in first-out region 215 and the electro-static discharge region 201; in other embodiments, alternatively, the first-in first-out region may be located between the drive circuit region and the electro-static discharge region.

In some embodiments, further referring to FIG. 14, the second transmission region 205 may further include: a serializer region 235, located between the drive circuit region 225 and the first-in first-out region 215.

In some embodiments, further referring to FIG. 14, the second transmission region 205 may further include: a pre-drive circuit region 245, located between the drive circuit region 225 and the first-in first-out region 215.

It should be noted that, in some embodiments, the second transmission region 205 may only include one of the serializer region 235 and the pre-drive circuit region 245; in other embodiments, the second transmission region 205 may include both the serializer region 235 and the pre-drive circuit region 245, and the pre-drive circuit region 245 is located between the drive circuit region 225 and the serializer region 235.

It should be noted that, regardless of whether the second transmission region 205 includes only two sub-regions (such as the first-in first-out region 215 and the drive circuit region 225), or three sub-regions (such as the first-in first-out region 215, the drive circuit region 225 and the serializer region 235, or the first-in first-out region 215, the drive circuit region 225 and the pre-drive circuit region 245), or four sub-regions (such as the first-in first-out region 215, the drive circuit region 225, the serializer region 235, and the pre-drive circuit region 245), the layout manner of the sub-regions in the second transmission region 205 along the direction X is not limited. FIG. 14 merely shows an example for ease of description.

In some embodiments, further referring to FIG. 14, the integrated circuit layout may further include: a data sampling pad region 207, a first power supply pad region 217, a second power supply pad region 227, and a ground pad region 237.

It should be noted that, in FIG. 14, DQ0, DQ1, DQ2, and DQ3 are used to indicate the data pads region 200; in FIG. 13, the reference sign DQ is not followed by a number, and does not specifically refer to a particular data pad region 200. In FIG. 14, RDQS is used to indicate the data sampling pad region 207, VDDQ is used to indicate the first power supply pad region 217, VCC is used to indicate the second power supply pad region 227, and VSS is used to indicate the ground pad region 237. FIG. 14 only schematically shows four data pad regions 200 located in the same row. In practical application, the number of data pad regions 200 in the integrated circuit layout is not limited. In addition, in FIG. 13 to FIG. 15, DqESD is used to indicate the electro-static discharge region 201, DqFDrv is used to indicate the drive circuit region 225, DqPDrv is used to indicate the pre-drive circuit region 245, DqP2S is used to indicate the serializer region 235, DqIB is used to indicate the input buffer region 213, DqFiFo is used to indicate the first-in first-out region 215, and DqLat is used to indicate the latch region 223.

In some embodiments, referring to FIG. 10, FIG. 14 and FIG. 15, the integrated circuit layout may further include: a first clock region 208, configured to define a first clock processing circuit 108; a second clock region 218, configured to define a second clock processing circuit 118, where arrangement of positions of the first clock region 208 and the second clock region 218 corresponds to arrangement of positions of the first transmission region 203 and the second transmission region 205. That is, along the direction X, the first clock region 208 and the second clock region 218 are arranged up and down.

It should be noted that, in FIG. 15, DQ0, DQ1, DQ2... DQ7 are used to indicate the data pad regions 200, RDQS is used to indicate the data sampling pad region 207, WCK is used to indicate a clock pad region 247, DM is used to indicate a data mask pad region 257, WCK1 is used to indicate a first clock region 208, WCK2 is used to indicate a second clock region 218, DPMUX1 is used to indicate a first module region 248, and DPMUX2 is used to indicate a second module region 268. FIG. 15 only schematically shows eight data pad regions 200 located in the same row. In practical application, the number of data pad regions 200 in the integrated circuit layout is not limited.

The integrated circuit layout may further include: a fifth bus region (not shown in the figure), configured to define a fifth bus 128; and a sixth bus region (not shown in the figure), configured to define a sixth bus 138. The first clock region 208 and the first transmission region 203 are connected through the fifth bus region. In an example, the first clock region 208 is connected to the latch region 223 in the first transmission region 203 through the fifth bus region. The second clock region 218 and the second transmission region 205 are connected through the sixth bus region. In an example, the second clock region 218 is connected to the first-in first-out region 215 in the second transmission region 205 through the sixth bus region.

In some embodiments, referring to FIG. 14 and FIG. 15, the integrated circuit layout may be divided into a first region I and a second region II. The first region I and the second region II each include a plurality of data pad regions 200 located in a same row, a plurality of electro-static discharge regions 201 located in a same row, a plurality of first transmission regions 203 located in a same row, and a plurality of second transmission regions 205 located in a same row. The first clock region 208 and the second clock region 218 are located between the first region I and the second region II.

In some embodiments, the integrated circuit layout further includes: a first module region 248, configured to define a first data selection module 148; a plurality of third bus regions 258, configured to define a plurality of third buses 158, where the third bus 158 connects the first data selection module 148 and the corresponding first transmission circuit 103; a second module region 268, configured to define a second data selection module 168, where the first module region 248 and the second module region 268 are located at a same side of the first transmission region 203 and the second transmission region 205, and arrangement of positions of the first module region 248 and the second module region 268 corresponds to arrangement of positions of the first transmission region 203 and the second transmission region 205; and a plurality of fourth bus regions 278, configured to define a plurality of fourth buses 178, where the fourth bus 178 connects the second data selection module 168 and the corresponding second transmission circuit 105.

In the integrated circuit layout provided by the embodiments of the present disclosure, a large gap exists between the latch region 223 and the first-in first-out region 215, which, on one hand, helps increase the gaps between the plurality of third bus regions 258, thereby reducing the parasitic capacitance between the third buses 158 formed according to the plurality of third bus regions 258 to improve the accuracy of the written data, and on the other hand, helps increase the gaps between the plurality of fourth bus regions 278, thereby reducing the parasitic capacitance between the fourth buses 178 formed according to the plurality of fourth bus regions 278 to improve the accuracy of the read data. In addition, because the first module region 248 and the second module region 268 are arranged up and down along the direction X, the third bus region 258 can be connected to the first transmission region 203 without bypassing the second module region 268, or the fourth bus region 278 can be connected to the second transmission region 205 without bypassing the first module region 248, which avoids an unnecessary bypassing length in the third bus region 258 or the fourth bus region 278, thereby helping further simplify the overall arrangement of the integrated circuit layout.

In some embodiments, referring to FIG. 10 and FIG. 15, the integrated circuit layout may further include: a data mask pad region 257, located in a same row with the data pad region 200 and configured to define a data mask pad 157; a third transmission region 267, located in a same row with the first transmission region 203 and configured to define a third transmission region 267; and a fourth transmission region 277, located in a same row with the second transmission region 205 and configured to define a fourth transmission circuit 177.

In some embodiments, referring to FIG. 10 and FIG. 15, the integrated circuit layout may further include: a seventh bus region 288, configured to define a seventh bus 188; and an eighth bus region 298, configured to define an eighth bus 198. The third transmission region 267 can be connected to the first module region 248 through the seventh bus region 288; the fourth transmission region 277 can be connected to the second module region 268 through the eighth bus region 298.

In some embodiments, referring to FIG. 15, along the direction X from the first transmission region 203 to the second transmission region 205, two initial third bus regions 258 have a largest length and a smallest length respectively; lengths of adjacent third bus regions 258 at odd-number positions among the plurality of third buses region 258 change according to a first trend, and lengths of adjacent third bus regions 258 at even-number positions among the plurality of third buses region 258 change according to a second trend. The first trend is one of ascending or descending, and the second trend is the other of ascending or descending. In this way, by configuring different lengths of two adjacent third bus regions 258, a direct opposite area between the two adjacent third bus regions 258 is reduced, thereby helping reduce the overall parasitic capacitance of the integrated circuit structure formed according to the integrated circuit layout.

In addition, the length of the seventh bus region 288 or the eighth bus region 298 not only changes according to the first trend with the lengths of adjacent third bus regions 258 at odd-number positions, but also changes according to the second trend with the lengths of adjacent third bus regions 258 at even-number positions.

In some embodiments, referring to FIG. 15, along the direction X from the first transmission region 203 to the second transmission region 205, two initial fourth bus regions 278 have a largest length and a smallest length respectively; lengths of adjacent fourth bus regions 278 at odd-number positions among the plurality of fourth bus regions 278 change according to a first trend, and lengths of adjacent fourth bus regions 278 at even-number positions among the plurality of fourth bus regions 278 change according to a second trend. The first trend is one of ascending or descending, and the second trend is the other of ascending or descending. In this way, by configuring different lengths of two adjacent fourth bus regions 278, a direct opposite area between the two adjacent fourth bus regions 278 is reduced, thereby helping reduce the overall parasitic capacitance of the integrated circuit structure formed according to the integrated circuit layout.

It should be noted that, referring to FIG. 15, the two initial third bus regions 258 or fourth bus regions 278 are two third bus regions 258 or fourth bus regions 278 corresponding to the data pad region DQ7 and the data pad region DQ0; the third bus regions 258 or fourth bus regions 278 at odd-number positions are the third bus regions 258 or fourth bus regions 278 corresponding to the data pad regions DQ7, DQ6, DQ5, and DQ4; the third bus regions 258 or fourth bus regions 278 at even-number positions are the third bus regions 258 or fourth bus regions 278 corresponding to the data pad regions DQ0, DQ1, DQ2, and DQ3.

In addition, if the lengths of the adjacent third bus regions 258 or fourth bus regions 278 at odd-number positions change according to an ascending trend, along the direction X, the first initial third bus region 258 or fourth bus region 278 has the smallest length, and the second initial third bus region 258 or fourth bus region 278 has the largest length. If the lengths of the adjacent third bus regions 258 or fourth bus regions 278 at odd-number positions change according to a descending trend, along the direction X, the first initial third bus region 258 or fourth bus region 278 has the largest length, and the second initial third bus region 258 or fourth bus region 278 has the smallest length.

In this way, the first transmission region 203 and the second transmission region 205 are located at two sides of the electro-static discharge region 201 respectively, which helps reduce the distances from the first transmission region 203 and the second transmission region 205 to the electro-static discharge region 201 and reduce the lengths of the first bus 104 and the second bus 106, thereby reducing the overall parasitic capacitance of the integrated circuit structure formed according to the integrated circuit layout, so as to reduce the power consumption of the integrated circuit structure. On the other hand, arranging the first transmission region 203 between the data pad 100 and the electro-static discharge circuit 101 helps increase the utilization of the integrated circuit layout, to improve the overall integration density of the integrated circuit structure formed according to the integrated circuit layout and reduce the overall layout area of the integrated circuit structure.

Those skilled in the art can understand that the above implementations are specific embodiments for implementing the present disclosure. In practical applications, various changes may be made to the above embodiments in terms of form and details without departing from the spirit and scope of the embodiments of the present disclosure. Any person skilled in the art may make changes and modifications to the embodiments without departing from the spirit and scope of the present disclosure. Therefore, the protection scope of the present disclosure should be subject to the scope defined by the claims.

1. An integrated circuit structure, comprising:
a data pad;
an electro-static discharge circuit, located at a side of the data pad and electrically connected to the data pad;
a first transmission circuit, located at a side of the electro-static discharge circuit which faces towards the data pad, wherein the first transmission circuit is electrically connected to the electro-static discharge circuit through a first bus; and
a second transmission circuit, located at a side of the electro-static discharge circuit which is away from the first transmission circuit, wherein the second transmission circuit is electrically connected to the electro-static discharge circuit through a second bus;
wherein one of the first transmission circuit and the second transmission circuit is configured to transmit data from the data pad to a memory array, and the other is configured to receive data from the memory array and transmit the data to the data pad.

2. The integrated circuit structure according to claim 1, wherein the first transmission circuit is configured to transmit the data from the data pad to the memory array, and the second transmission circuit is configured to receive the data from the memory array and transmit the data to the data pad.

3. The integrated circuit structure according to claim 1, wherein the first transmission circuit comprises:
an input buffer circuit, configured to receive data transmitted by the data pad corresponding to the input buffer circuit; and
a latch circuit, configured to receive and latch data outputted by the input buffer circuit, and output latched data in response to a write clock signal.

4. The integrated circuit structure according to claim 3, wherein the input buffer circuit is located between the latch circuit and the electro-static discharge circuit.

5. The integrated circuit structure according to claim 1, wherein the second transmission circuit comprises:
a first-in first-out circuit, configured to receive and transmit data from the memory array; and
a drive circuit, configured to receive data outputted by the first-in first-out circuit, and output the data to the data pad, wherein the drive circuit is located between the electro-static discharge circuit and the first-in first-out circuit.

6. The integrated circuit structure according to claim 5, wherein the second transmission circuit further comprises:
a serializer circuit, located between the drive circuit and the first-in first-out circuit, and configured to serialize the data outputted by the first-in first-out circuit, and transmit serialized data to the drive circuit.

7. The integrated circuit structure according to claim 5, wherein the second transmission circuit further comprises:
a pre-drive circuit, located between the drive circuit and the first-in first-out circuit.

8. The integrated circuit structure according to claim 1, further comprising:
a first clock processing circuit, configured to provide a first clock signal, wherein the first transmission circuit outputs the data from the data pad in response to the first clock signal; and
a second clock processing circuit, configured to provide a second clock signal, wherein the second transmission circuit outputs the data from the memory array in response to the second clock signal;
wherein arrangement of positions of the first clock processing circuit and the second clock processing circuit corresponds to arrangement of positions of the first transmission circuit and the second transmission circuit.

9. The integrated circuit structure according to claim 1, further comprising:
a first data selection module, connected to a plurality of first transmission circuits through a plurality of third buses, wherein each of the third buses corresponds to at least one of the first transmission circuits; and
a second data selection module, connected to a plurality of second transmission circuits through a plurality of fourth buses, wherein each of the fourth buses corresponds to at least one of the second transmission circuits;
wherein the first data selection module and the second data selection module are connected to the memory array, and are located at a same side of the first transmission circuit and the second transmission circuit, and arrangement of positions of the first data selection module and the second data selection module corresponds to arrangement of positions of the first transmission circuit and the second transmission circuit.

10. The integrated circuit structure according to claim 1, further comprising:
a plurality of data pads located in a same row, a plurality of electro-static discharge circuits located in a same row, a plurality of first transmission circuits located in a same row, and a plurality of second transmission circuits located in a same row, wherein the data pad, the electro-static discharge circuit, the first transmission circuit, and the second transmission circuit correspond to each other.

11. The integrated circuit structure according to claim 1, further comprising:
a data mask pad, located in a same row with the data pad and configured to transmit a data mask signal;
a third transmission circuit, located in a same row with the first transmission circuit and configured to transmit the data mask signal from the data mask pad; and
a fourth transmission circuit, located in a same row with the second transmission circuit and configured to receive the data mask signal from the memory array and transmit the data mask signal to the data mask pad.

12. A memory, comprising:
a memory cell; and
the integrated circuit structure according to claim 1.

13. An integrated circuit layout, comprising:
a data pad region, configured to define positions of a plurality of data pads located in a same row;
an electro-static discharge region, located at a side of the data pad region, and configured to define positions of a plurality of electro-static discharge circuits located in a same row;
a first transmission region, located between the data pad region and the electro-static discharge region and configured to define positions of a plurality of first transmission circuits located in a same row, wherein the first transmission circuit is electrically connected to the electro-static discharge circuit through a first bus; and
a second transmission region, located at a side of the electro-static discharge region which is away from the first transmission region and configured to define positions of a plurality of second transmission circuits located in a same row, wherein the second transmission circuit is electrically connected to the data pad through a second bus;
wherein one of the first transmission circuit and the second transmission circuit is configured to transmit data from the data pad to a memory array, and the other is configured to receive data from the memory array and transmit the data to the data pad.

14. The integrated circuit layout according to claim 13, wherein the first transmission circuit is configured to transmit the data from the data pad to the memory array, and the second transmission circuit is configured to receive the data from the memory array and transmit the data to the data pad.

15. The integrated circuit layout according to claim 13, wherein the first transmission region comprises:
an input buffer region, configured to define a plurality of input buffer circuits located in a same row; and
a latch region, located at a side of the input buffer region which is away from the electro-static discharge region and configured to define a plurality of latch circuits located in a same row.

16. The integrated circuit layout according to claim 13, wherein the second transmission region comprises:
a first-in first-out region, configured to define a plurality of first-in first-out circuits located in a same row; and
a drive circuit region, located between the first-in first-out region and the electro-static discharge region, and configured to define a plurality of drive circuits located in a same row.

17. The integrated circuit layout according to claim 13, further comprising:
a first clock region, configured to define a first clock processing circuit; and
a second clock region, configured to define a second clock processing circuit, wherein arrangement of positions of the first clock region and the second clock region corresponds to arrangement of positions of the first transmission region and the second transmission region.

18. The integrated circuit layout according to claim 13, further comprising:
a first module region, configured to define a first data selection module;
a plurality of third bus regions, configured to define a plurality of third buses, wherein the third bus connects the first data selection module and the corresponding first transmission circuit;
a second module region, configured to define a second data selection module, wherein the first module region and the second module region are located at a same side of the first transmission region and the second transmission region, and arrangement of positions of the first module region and the second module region corresponds to arrangement of positions of the first transmission region and the second transmission region; and
a plurality of fourth bus regions, configured to define a plurality of fourth buses, wherein the fourth bus connects the second data selection module and the corresponding second transmission circuit.

19. The integrated circuit layout according to claim 18, wherein along a direction from the first transmission region to the second transmission region, two initial third bus regions have a largest length and a smallest length respectively; lengths of adjacent third bus regions at odd-number positions among the plurality of third bus regions change according to a first trend, and lengths of adjacent third bus regions at even-number positions among the plurality of third bus regions change according to a second trend; the first trend is one of ascending or descending, and the second trend is the other of ascending or descending.

20. The integrated circuit layout according to claim 18, wherein along a direction from the first transmission region to the second transmission region, two initial fourth bus regions have a largest length and a smallest length respectively; lengths of adjacent fourth bus regions at odd-number positions among the plurality of fourth bus regions change according to a first trend; lengths of adjacent fourth bus regions at even-number positions among the plurality of fourth bus regions change according to a second trend; the first trend is one of ascending or descending, and the second trend is the other of ascending or descending.
